(19) United States
(12) Patent Application Publication
(10) Pub. No.: US 2023/0118890 A1
(43) Pub. Date: Apr. 20, 2023

(54) SEMICONDUCTOR DEVICE, AND MANUFACTURING METHOD THEREFOR

(71) Applicant: Mitsubishi Electric Corporation, Chiyoda-ku, Tokyo (JP)

(72) Inventors: Junji FUJINO, Chiyoda-ku, Tokyo (JP); Michio OGAWA, Chiyoda-ku, Tokyo (JP); Chika KAWAZOE, Chiyoda-ku, Tokyo (JP); Fumio WADA, Chiyoda-ku, Tokyo (JP); Satoru ISHIKAWA, Chiyoda-ku, Tokyo (JP)

(73) Assignee: Mitsubishi Electric Corporation, Chiyoda-ku, Tokyo (JP)

(21) Appl. No.: 17/798,100

(22) PCT Filed: Mar. 25, 2021
(86) PCT No.: PCT/JP2021/012535

§ 371 Date: Aug. 8, 2022

(30) Foreign Application Priority Data
Mar. 26, 2020 (JP) 2020-056429

(51) Int. Cl. H01L 23/15; H01L 23/31; H01L 23/367; H01L 23/00

(52) U.S. Cl. CPC H01L 23/15; H01L 23/3128; H01L 23/3677; H01L 24/48; H01L 2924/3511; H01L 2924/13055; H01L 2224/48091

(57) ABSTRACT

A power module includes an insulating substrate, a heat dissipation member, and an electrode plate. An IGBT and a diode are mounted on the insulating substrate. The heat dissipation member is bonded to the insulating substrate by first solder. The electrode plate is disposed so as to overlap at least a part of the semiconductor element. The main surface of the insulating substrate is curved so as to have a shape convex toward the heat dissipation member. The first solder is thicker at the edges than at the center in a plan view. The semiconductor element is bonded to the electrode plate by second solder.

### TECHNICAL FIELD

The present disclosure relates to a semiconductor device and a manufacturing method therefor.

### BACKGROUND ART

A so-called power module as a semiconductor device is becoming widespread in various products from industrial machines to home appliances and information terminals. A power module mounted on an electric vehicle is required to have high reliability. It is further required that the power module for an electric vehicle be high in operating temperature and high in efficiency. It is therefore required that the power module for an electric vehicle be in a package form applicable to a silicon-carbide semiconductor which is highly likely to become the mainstream in the future.

For example, in Japanese Patent Laying-Open No. 2016-058563 (PTL 1), the thickness and linear expansion coefficient of an encapsulant resin are adjusted to fall within appropriate numerical ranges. This causes an insulating substrate to curve so as to have a shape convex downward and thus prevents air from being caught in a heat dissipation grease portion between a heat dissipation member and the insulating substrate.

### CITATION LIST

### Patent Literature

PTL 1: Japanese Patent Laying-Open No. 2016-058563

### SUMMARY OF INVENTION

### Technical Problem

In the configuration where the curved and inclined insulating substrate is bonded onto the base plate as disclosed in Japanese Patent Laying-Open No. 2016-058563, contact of a wire tool varies when the wiring for circuit formation is wire-bonded to the semiconductor element on the insulating substrate. That is, when a plurality of semiconductor elements are mounted on the insulating substrate, the inclination angle of the surface of each of the plurality of semiconductor element from the horizontal direction differs in a manner that depends on a location of the semiconductor element, for example. This makes it necessary to readjust the contact of the wire tool each time each of the plurality of semiconductor elements is wire-bonded. This may cause, when the adjustment is insufficient, the wire tool to damage the semiconductor element and make it difficult to wire-bond the wiring with high reliability.

The present disclosure has been made in view of the above-described problems.

It is therefore an object of the present disclosure to provide a semiconductor device with high reliability including a circuit stably connected to a semiconductor element mounted on an insulating substrate having a curved main surface, and a manufacturing method therefor.

### Solution to Problem

A semiconductor device according to the present embodiment includes an insulating substrate, a heat dissipation member, and an electrode plate. A semiconductor element is mounted on the insulating substrate. The heat dissipation member is bonded to the insulating substrate by first solder. The electrode plate is disposed so as to overlap at least a part of the semiconductor element. A main surface of the insulating substrate is curved so as to have a shape convex toward the heat dissipation member. The first solder is thicker at the edges than at the center in a plan view. The semiconductor element is bonded to the electrode plate by second solder.

Under a manufacturing method for a semiconductor device according to the present embodiment, a heat dissipation member and an insulating substrate are bonded together by first solder. A semiconductor element is bonded to the insulating substrate. After the bonding with the first solder and the bonding the semiconductor element, an electrode plate overlapping at least a part of the semiconductor element is bonded to the semiconductor element by second solder. The insulating substrate is bonded to the heat dissipation member to cause a main surface of the insulating substrate to curve so as to have a shape convex toward the heat dissipation member. The first solder is formed thicker at the edges than at the center in a plan view.

### Advantageous Effects of Invention

According to the present disclosure, it is possible to provide the semiconductor device with high reliability including a circuit stably connected to a semiconductor element mounted on an insulating substrate having a curved main surface, and the manufacturing method therefor.

### BRIEF DESCRIPTION OF DRAWINGS

FIG. 1 is a schematic cross-sectional view of a configuration of a power module according to a first embodiment.

FIG. 2 is a schematic cross-sectional view of a first modification of the configuration of the power module according to the first embodiment.

FIG. 3 is a schematic cross-sectional view of a second modification of the configuration of the power module according to the first embodiment.

FIG. 4 is a schematic cross-sectional view of a third modification of the configuration of the power module according to the first embodiment.

FIG. 5 is a schematic cross-sectional view of a fourth modification of the configuration of the power module according to the first embodiment.

FIG. 6 is a schematic cross-sectional view of a fifth modification of the configuration of the power module according to the first embodiment.

FIG. 7 is a schematic cross-sectional view of the power module according to the first embodiment illustrated in FIG. 2, illustrating a first process of a manufacturing method for the power module.

FIG. 8 is a schematic cross-sectional view of the power module according to the first embodiment illustrated in FIG. 2, illustrating a second process of the manufacturing method for the power module.

FIG. 9 is a schematic cross-sectional view of the power module according to the first embodiment illustrated in FIG. 2, illustrating a third process of the manufacturing method for the power module.

FIG. 10 is a schematic cross-sectional view of the power module according to the first embodiment illustrated in FIG. 2, illustrating a fourth process of the manufacturing method for the power module.

FIG. 11 is a schematic cross-sectional view of the power module according to the first embodiment illustrated in FIG. 1, illustrating a first process of the manufacturing method for the power module.

FIG. 12 is a schematic cross-sectional view of the power module according to the first embodiment illustrated in FIG. 1, illustrating a second process of the manufacturing method for the power module.

FIG. 13 is a schematic cross-sectional view of the power module according to the first embodiment illustrated in FIG. 1, illustrating a third process of the manufacturing method for the power module.

FIG. 14 is a schematic cross-sectional view of a configuration of a power module according to a second embodiment.

FIG. 15 is a schematic cross-sectional view of a configuration of a power module according to a third embodiment.

FIG. 16 is a schematic cross-sectional view of the power module according to the third embodiment, illustrating a first process of a manufacturing method for the power module.

FIG. 17 is a schematic cross-sectional view of the power module according to the third embodiment, illustrating a second process of the manufacturing method for the power module.

FIG. 18 is a schematic cross-sectional view of the power module according to the third embodiment, illustrating a third process of the manufacturing method for the power module.

FIG. 19 is a schematic cross-sectional view of the power module according to the third embodiment, illustrating a fourth process of the manufacturing method for the power module.

FIG. 20 is a schematic cross-sectional view of a configuration of a power module according to a fourth embodiment.

FIG. 21 is a schematic cross-sectional view of the power module according to the fourth embodiment, illustrating a first process of a manufacturing method for the power module.

FIG. 22 is a schematic cross-sectional view of the power module according to the fourth embodiment, illustrating a second process of the manufacturing method for the power module.

FIG. 23 is a schematic cross-sectional view of a configuration of a power module according to a fifth embodiment.

FIG. 24 is a schematic cross-sectional view of a configuration of a power module according to a sixth embodiment.

FIG. 25 is a schematic cross-sectional view of a configuration of a power module according to a seventh embodiment.

FIG. 26 is a graph showing a result of measuring a maximum length of cracks formed at an edge of first solder.

FIG. 27 is an ultrasonic testing image of the edge of the first solder after temperature cycle testing conducted on a first sample.

FIG. 28 is an ultrasonic testing image of the edge of the first solder after the temperature cycle testing conducted on a third sample.

### DESCRIPTION OF EMBODIMENTS

Hereinafter, a power module 100 as a semiconductor device according to the present embodiment will be described with reference to the drawings. For convenience of description, an X direction, a Y direction, and a Z direction are introduced.

### First Embodiment

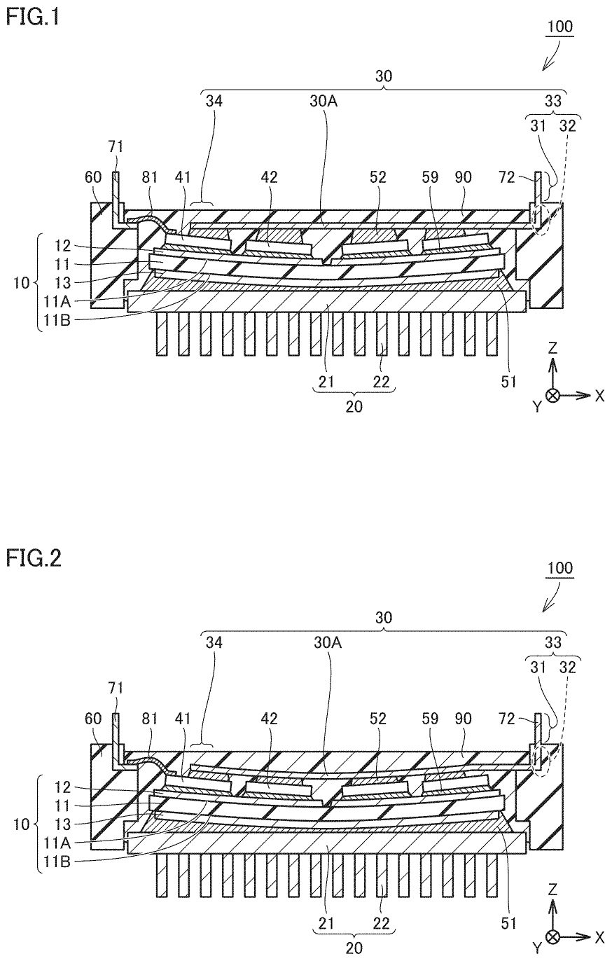

FIG. 1 is a schematic cross-sectional view of a configuration of a power module according to a first embodiment. With reference to FIG. 1, power module 100 according to the present embodiment mainly includes an insulating substrate 10, a heat dissipation member 20, and an electrode plate 30.

Insulating substrate 10 includes a base member 11, a conductor layer 12, and a conductor layer 13. Base member 11 has, for example, a rectangular shape in a plan view and has a thickness along the Z direction. Base member 11 has one surface 11A as an upper main surface in the Z direction and other surface 11B on a side opposite from one surface 11A, that is, a lower main surface in the Z direction. Conductor layer 12 is a thin plate-shaped conductor material, and at least one conductor layer 12 is bonded onto one surface 11A. Conductor layer 13 is a thin plate-shaped conductor material, and at least one conductor layer 13 is bonded onto other surface 11B.

A main surface of insulating substrate 10 means a surface extending along the XY plane of an object obtained by bonding thin conductor layer 12 and thin conductor layer 13 to one surface 11A and other surface 11B, respectively. Therefore, the main surface of insulating substrate 10 extends in substantially the same direction as one surface 11A and other surface 11B. Therefore, the main surface of insulating substrate 10 in its entirety, and one surface 11A and other surface 11B may be considered to be the same hereinafter.

An integrated gate bipolar transistor (IGBT) 41 and a diode 42 as semiconductor elements are mounted on conductor layer 12 of insulating substrate 10. Such semiconductor elements are constructed in chip form. In general, as illustrated in FIG. 1, IGBT 41 as a second semiconductor element is disposed outside relative to diode 42 as a first semiconductor element in the plan view. The configuration, however, is not limited to the above, and IGBT 41 may be disposed inside relative to diode 42 in the plan view.

Heat dissipation member 20 includes a base plate 21 and fins 22. Base plate 21 is a plate-shaped member having a surface extending along the XY plane. Fins 22 are members extending in the Z direction from, for example, a lowermost surface of base plate 21 in the Z direction. The plurality of fins 22 extend downward in the Z direction from the lowermost surface of base plate 21 at intervals in the X direction and the Y direction. Note that fins 22 may be integrated with or separated from base plate 21.

An uppermost surface, in the Z direction, of base plate 21 of heat dissipation member 20 is bonded to the lower main surface of insulating substrate 10 by first solder 51. Insulating substrate 10 protrudes toward heat dissipation member 20, that is, downward in the Z direction, and has the main surface curved so as to have a shape convex over a plurality of IGBTs 41 and diodes 42. That is, insulating substrate 10 is curved a such that other surface 11B of base member 11 has a convex shape as viewed from the outside, and one surface 11A has a concave shape as viewed from the outside. The convex shape of insulating substrate 10 is single convex shape extending across FIG. 1 in the X direction, and the single convex shape causes all of the plurality of IGBTs 41 and diodes 42 to slightly incline from the horizontal direction. This makes the center of the lower main surface of insulating substrate 10 in the X direction in FIG. 1 closer to heat dissipation member 20 in the Z direction than the edges of the lower main surface in the X direction in FIG. 1. This makes the center of first solder 51 in the plan view thicker in the Z direction than the edges of first solder 51. That is, first solder 51 gradually increases in thickness from the center toward the edges in the plan view. In other words, the thickness of first solder 51 monotonously increases from the center toward the edges.

First solder 51 bonds with the whole surface of conductor layer 13 on other surface 11B. The whole surface here is not limited to the complete whole surface, and includes, for example, a case where first solder layer 51 covers at least 95% of the surface area of conductor layer 13.

Electrode plate 30 is disposed so as to overlap at least a part of IGBT 41 and diode 42 in the plan view. That is, for example, electrode plate 30 may overlap only a part of IGBT 41 in plan view, or may overlap all IGBT 41. Electrode plate 30 is disposed above IGBT 41 and diode 42 in the Z direction at a distance from IGBT 41 and diode 42. Electrode plate 30 illustrated in FIG. 1 has a planar shape whose surface extends along the XY plane. That is, the surface of electrode plate 30 illustrated in FIG. 1 extending along the XY plane has almost no curved portion. IGBT 41 and diode 42 are bonded to electrode plate 30 by second solder 52. Here, main electrodes (not illustrated) formed in IGBT 41 and diode 42 are bonded to electrode plate 30 by second solder 52. This forms a circuit including IGBT 41, diode 42, and electrode plate 30. Further, IGBT 41 and diode 42 are bonded to conductor layer 12 of insulating substrate 10 by a conductive member 59.

Power module 100 further includes a frame member 60 in an outer region in the plan view. Frame member 60 is disposed so as to surround insulating substrate 10 on which IGBT 41 and diode 42 are mounted at a distance from insulating substrate 10 in the X direction and the Y direction, for example. Furthermore, frame member 60 is disposed so as to surround base plate 21 that is at least a part of heat dissipation member 20, and (at least a part of) a main body 30A that is a part of electrode plate 30, for example. Note that base plate 21 may be bonded to frame member 60 by an adhesive (not illustrated). Further, main body 30A may be partially brought into contact with frame member 60 or embedded in frame member 60. This causes electrode plate 30 to be disposed in frame member 60 so as to face insulating substrate 10 in the Z direction.

A signal electrode 71 is disposed inside frame member 60. More specifically, signal electrode 71 is disposed so as to be partially embedded in frame member 60. Signal electrode 71 includes a portion exposed outside frame member 60, a portion embedded in frame member 60, and a portion exposed from inside frame member 60. Note that the portion of signal electrode 71 exposed from inside frame member 60 is embedded in encapsulant 90 as described later. Herein, as described above, the portion of signal electrode 71 inside frame member 60 that is embedded in encapsulant 90 but exposed from at least frame member 60 in the form of a final product may be expressed as “exposed from frame member 60”. Among the portions, the portion of signal electrode 71 facing upward in the Z direction inside frame member 60 is electrically connected to IGBT 41 and diode 42 by a bonding wire 81.

Further, main body 30A of electrode plate 30 has a portion extending in the horizontal direction and facing IGBT 41 and diode 42, and a portion bent from the portion extending in the horizontal direction and extending in the Z direction. Main body 30A extends in the Z direction in a rightmost region in the X direction in FIG. 1. Of the portion of main body 30A extending in the Z direction and the portion bent from the portion extending in the Z direction and extending in the horizontal direction in the rightmost region in the X direction in FIG. 1, the rightmost region in FIG. 1 is a main terminal-side edge 33 as a main terminal 72. On the other hand, a leftmost edge in the X direction in FIG. 1 of the portion of main body 30A extending in the horizontal direction is a semiconductor element-side edge 34. Semiconductor element-side edge 34 is an edge on a side opposite from main terminal-side edge 33. As described above, electrode plate 30 includes main terminal-side edge 33 and semiconductor element-side edge 34.

Main terminal-side edge 33 has a first portion 31 extending in the Z direction and exposed outside frame member 60 and a second portion 32 embedded in frame member 60. Second portion 32 includes a portion where main terminal 72 is bent. This causes electrode plate 30 to electrically connect the inside and the outside of frame member 60 in the plan view.

As described above, in FIG. 1, the portion of electrode plate 30 extending in the horizontal direction, that is, along the XY plane, is integrated with main terminal 72. This causes electrode plate 30 to electrically connect to main terminal 72.

Note that signal electrode 71 and main body 30A of electrode plate 30 including main terminal 72 may be made of a single lead frame divided into two.

The region that is surrounded by frame member 60 and base plate 21 and where insulating substrate 10 and the like are disposed is filled with encapsulant 90. That is, IGBT 41 and diode 42 are encapsulated in encapsulant 90 as an encapsulant resin. First solder 51 is in contact with encapsulant 90.

Next, materials, dimensions, and the like of each of the above-described members will be described.

Base member 11 that is a part of insulating substrate 10 is made of, for example, aluminum nitride. Alternatively, base member 11 may be made of, for example, either alumina or silicon nitride instead of aluminum nitride. As described above, base member 11 is preferably made of a ceramic material. The material, however, is not limited to the above, and base member 11 may be made of either a glass epoxy resin or a metal base resin. Alternatively, base member 11 may be low temperature co-fired ceramics (LTCC) that is a low temperature fired substrate. Base member 11 has dimensions of, for example, 65 mm*65 mm*a thickness of 0.64 mm.

Conductor layers 12, 13 are made of, for example, copper. Alternatively, conductor layers 12, 13 may be made of, for example, either nickel or nickel-plated aluminum instead of copper. Each of a plurality of conductor layers 12 obtained by division has dimensions of, for example, 30 mm*61 mm*a thickness of 0.4 mm. Conductor layer 13 has dimensions of, for example, 61 mm*61 mm*a thickness of 0.4 mm.

Base plate 21 and fins 22 constituting heat dissipation member 20 are made of, for example, aluminum. The material, however, is not limited to the above, and heat dissipation member 20 may be made of an aluminum alloy material such as a so-called A6063. Alternatively, heat dissipation member 20 may be made of either copper or a copper alloy. The surface of each material constituting heat dissipation member 20 may be plated with nickel or the like.

Note that heat dissipation member 20 illustrated in FIG. 1 includes base plate 21 and fins 22. However, when the cooling capacity of base plate 21 is sufficiently high, heat dissipation member 20 may be constituted of only base plate 21 without fins 22. Further, base plate 21 of heat dissipation member 20 may include either an air-cooling fan or a heat sink, and in this case as well, may or may not have fins 22.

Main body 30A of electrode plate 30 and signal electrode 71 are preferably made of a metal material such as copper.

The chips of IGBT 41 and diode 42 are made of silicon. Note that, instead of diode 42, any one of a so-called integrated circuit (IC) chip or a chip on which a so-called metal-oxide-semiconductor field effect transistor (MOSFET) is mounted may be used. The chip of IGBT 41 has dimensions of, for example, 13 mm*13 mm*a thickness of 0.2 mm. The chip of diode 42 has dimensions of, for example, 13 mm* 10 mm*a thickness of 0.2 mm.

In FIG. 1, IGBT 41 and diode 42 are arranged in two pairs, that is, a so-called 2in1 module configuration. The configuration, however, is not limited to the above, and for example, IGBT 41 and diode 42 may be arranged in one pair, that is, a so-called 1in1 module configuration. Alternatively, for example, IGBT 41 and diode 42 may be arranged in six pairs, that is, a so-called 6in1 module configuration. Alternatively, instead of the above-described configurations, for example, a discrete component on which only one power semiconductor element is mounted may be used.

IGBT 41 includes signal electrodes provided for a gate signal, a temperature sensor, and the like (not illustrated). Bonding wires are used to connect such signal electrodes to frame member 60. For this reason, as illustrated in FIG. 1, IGBT 41 is generally disposed on the outer side adjacent to frame member 60 in the plan view, and diode 42 is generally disposed on the inner side.

Here, the portion of first solder 51 that overlaps the center of insulating substrate 10 in the plan view is smaller in thickness and is thus significantly low in thermal resistance. From this viewpoint, it may be preferable that IGBT 41 that is larger in amount of heat generated than diode 42 be disposed at the center of insulating substrate 10. However, even with IGBT 41 disposed on the outer side in the plan view as illustrated in FIG. 1, when heat of IGBT 41 is conducted to insulating substrate 10, the center of insulating substrate 10 becomes highest in temperature due to thermal interference. Therefore, IGBT 41 may be disposed on the outer side relative to diode 42. It is preferable that the center of insulating substrate 10 where the temperature becomes highest due to thermal interference and the center, that is, the tip, of the convex shape formed by insulating substrate 10 curved downward substantially coincide with each other.

First solder 51 has a thickness of, for example, 0.2 mm at the center in the X direction in FIG. 1. On the other hand, first solder 51 has a thickness of, for example, 0.4 mm at the edges in the X direction in FIG. 1. The thickness of second solder 52 illustrated in FIG. 1 varies in a manner that depends on the place where second solder 52 is disposed. That is, the maximum thickness of second solder 52 between electrode plate 30 and diode 42 is larger than the maximum thickness of second solder 52 between electrode plate 30 and IGBT 41.

First solder 51 and second solder 52 are preferably made of, for example, so-called 96Sn—3.5Ag—0.5Cu. That is, such solders are made of a material containing 96.5 mass % of tin, 3.5 mass % of silver, and 0.5 mass % of copper. The material, however, is not limited to the above. First solder 51 and second solder 52 may be made of a material containing 98.5 mass % of tin, 1 mass % of silver, and 0.5 mass % of copper. First solder 51 and second solder 52 may be made of a material containing 96 mass % of tin, 3 mass % of antimony, and 1 mass % of silver.

Conductive member 59 may be made of a solder material that is the same in composition as first solder 51 and second solder 52. Conductive member 59, however, is not limited to the solder material, and may be made of another type of conductive material. For example, conductive member 59 may be a so-called Cu—Sn paste containing a dispersed copper powder and isothermally solidified. The Cu—Sn paste can have high heat resistance. Alternatively, conductive member 59 may be a so-called nanosilver paste containing low temperature fired nanosilver particles used for bonding.

Frame member 60 is made of a polyphenylene sulfide (PPS) resin. The material of frame member 60, however, is not limited to the above, and frame member 60 may be made of a liquid crystal polymer resin, that is, an LCP resin. The outermost portion of frame member 60 has dimensions of, for example, 75 mm*75 mm*a thickness of 8 mm. The thickness of 8 mm is a dimension in the Z direction.

In frame member 60 illustrated in FIG. 1, an inner wall portion at the position where main terminal 72 is embedded in the Z direction, that is, the thickness direction and the position where base plate 21 is disposed is positioned on the outer side relative to an inner wall portion at other positions. An outer wall of base plate 21 is uniform in position in the X direction (Y direction) over a whole section in the thickness direction. As described above, in frame member 60, a side wall at at least either the position where main terminal 72 is embedded in the thickness direction or the position where base plate 21 is disposed may be thinner than the other position, that is, the center in the thickness direction.

Bonding wire 81 is preferably a thin aluminum wire. Bonding wire 81, however, is not limited to the above and may be any one of a thin copper wire, a thin wire of copper coated with aluminum, or a gold wire. It is preferable that a diameter of a cross section of bonding wire 81 taken along a plane orthogonal to the extending direction of bonding wire 81 be, for example, 0.15 mm.

As encapsulant 90, a silica filler-containing epoxy resin is used, for example. Encapsulant 90 is not limited to the above, and a silicone gel or the like may be used as encapsulant 90.

FIG. 2 is a schematic cross-sectional view of a modification of the configuration of the power module according to the first embodiment. With reference to FIG. 2, a power module 100 according to the modification of the present embodiment is basically the same in configuration as power module 100 illustrated in FIG. 1. Therefore, in FIG. 2, the same components as the components illustrated in FIG. 1 are denoted by the same reference numerals, and no description will be given below of such components as long as their functions and the like are the same. The same applies to the following power modules unless otherwise specified.

Note that, in power module 100 illustrated in FIG. 2, the main surface of main body 30A of electrode plate 30 facing insulating substrate 10 is curved along the shape of insulating substrate 10 convex toward heat dissipation member 20. That is, on insulating substrate 10, the main surface of electrode plate 30 is curved so as to have a shape convex toward heat dissipation member 20 like insulating substrate 10. As with insulating substrate 10, electrode plate 30 is curved such that the lower surface has a convex shape as viewed from the outside and the upper surface has a concave shape as viewed from the outside. In this respect, electrode plate 30 illustrated in FIG. 2 is different from electrode plate 30 illustrated in FIG. 1 in that the surface extending along the XY plane has almost no curved portion.

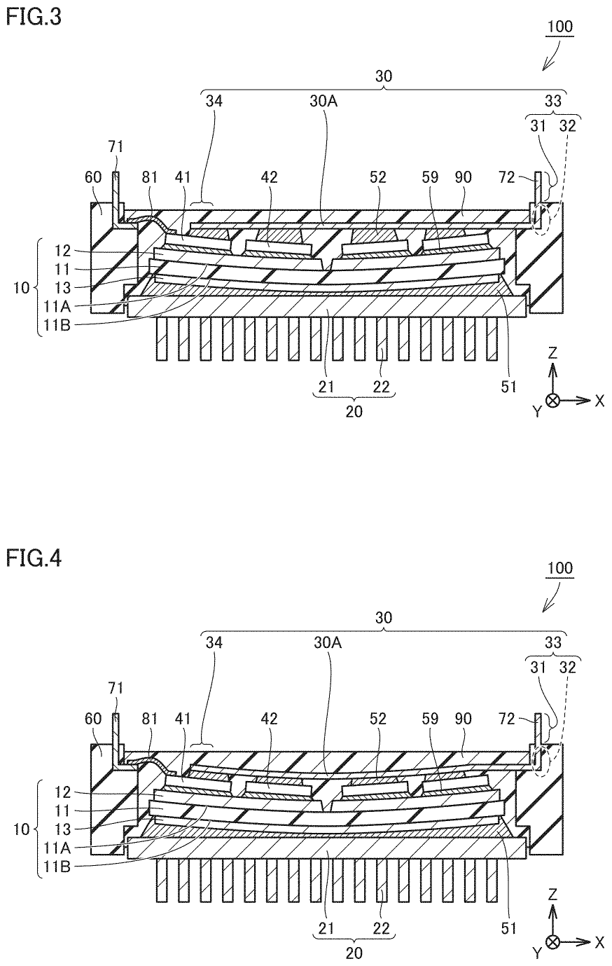

FIG. 3 is a schematic cross-sectional view of a second modification of the configuration of the power module according to the first embodiment. FIG. 4 is a schematic cross-sectional view of a third modification of the configuration of the power module according to the first embodiment. With reference to FIG. 3, the configuration is basically the same as the configuration illustrated in FIG. 1, but is different from the configuration illustrated in FIG. 1 in that conductor layer 12 on one surface 11A is formed thicker than conductor layer 13 on other surface 11B. Likewise, with reference to FIG. 4, the configuration is basically the same as the configuration illustrated in FIG. 2, but is different from the configuration illustrated in FIG. 2 in that conductor layer 12 on one surface 11A is formed thicker than conductor layer 13 on other surface 11B.

When conductor layer 12 on one surface 11A is formed thicker than conductor layer 13 on other surface 11B, insulating substrate 10 is curved so as to have a shape convex toward heat dissipation member 20.

Further, a first region on one surface 11A where conductor layer 12 is not bonded and a second region on other surface 11B where conductor layer 13 is not bonded are considered. When the first region is larger in area than the second region, insulating substrate 10 is curved so as to have a shape convex toward heat dissipation member 20. Furthermore, for example, when conductor layer 12 on one surface 11A is formed thicker than conductor layer 13 on other surface 11B, insulating substrate 10 is curved so as to have a shape convex toward heat dissipation member 20 even when the first region and the second region are the same in area.

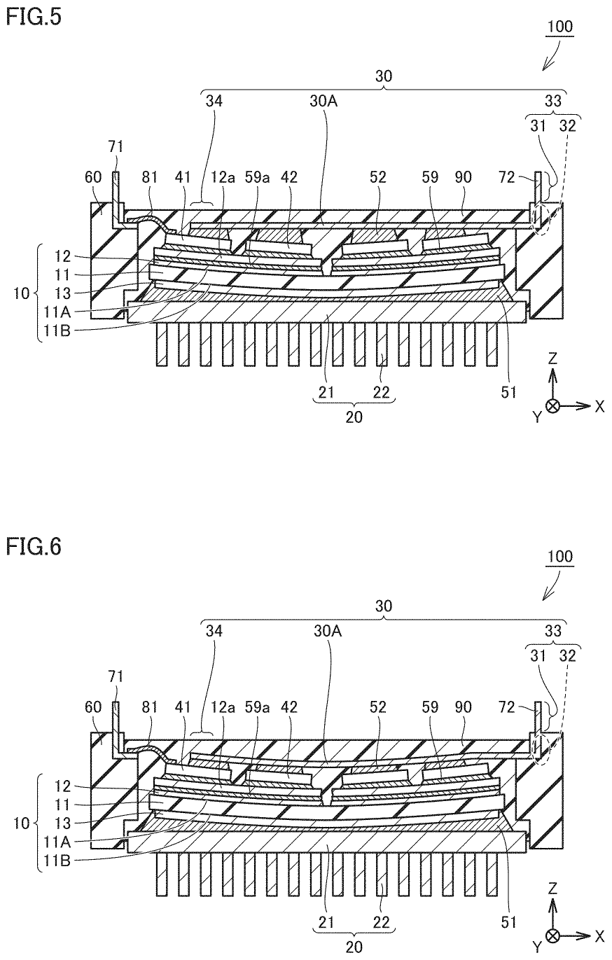

FIG. 5 is a schematic cross-sectional view of a fourth modification of the configuration of the power module according to the first embodiment. FIG. 6 is a schematic cross-sectional view of a fifth modification of the configuration of the power module according to the first embodiment. With reference to FIG. 5, the configuration is basically the same as the configuration illustrated in FIG. 1, but other conductor layer 12a is disposed between conductor layer 12 on one surface 11A, and IGBT 41 and diode 42. Other conductor layer 12a is bonded by fourth solder 59a so as to overlap conductor layer 12. Likewise, with reference to FIG. 6, the configuration is basically the same as the configuration illustrated in FIG. 2, but other conductor layer 12a is disposed between conductor layer 12 on one surface 11A, and IGBT 41 and diode 42. Other conductor layer 12a is bonded by fourth solder 59a so as to overlap conductor layer 12. In this respect, FIGS. 5 and 6 are different from FIGS. 1 and 2 in which other conductor layer 12a and fourth solder 59a are not provided. This makes, as illustrated in FIGS. 5 and 6, as in FIGS. 3 and 4, the conductor layer on one surface 11A of base member 11 substantially thicker than conductor layer 13 on other surface 11B. Therefore, as illustrated in FIGS. 5 and 6, as in FIGS. 3 and 4, insulating substrate 10 is curved so as to have a shape convex toward heat dissipation member 20.

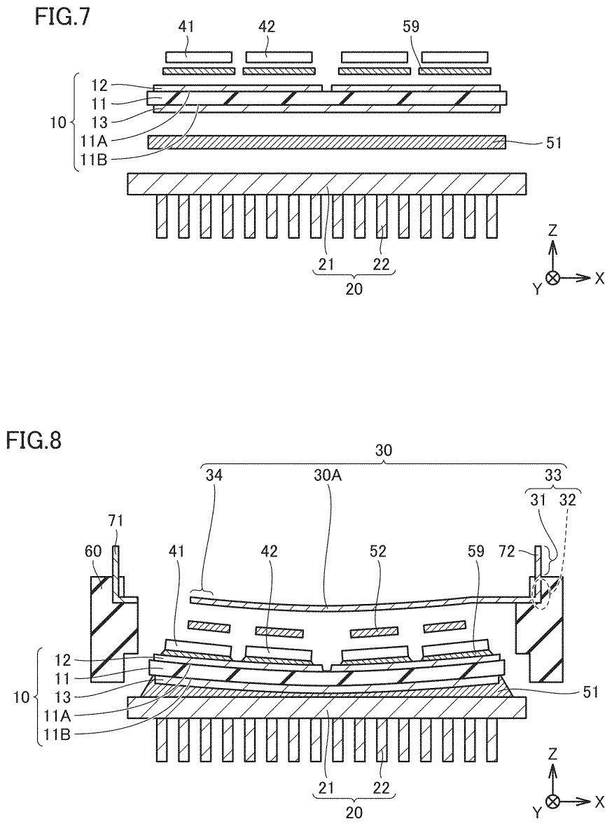

Next, a manufacturing method for power module 100 according to the present embodiment will be described with reference to FIGS. 7 to 13. Note that, in FIGS. 7 to 10, a manufacturing method for power module 100 illustrated in FIG. 2 will be described.

FIG. 7 is a schematic cross-sectional view of the power module according to the first embodiment illustrated in FIG. 2, illustrating a first process of the manufacturing method for the power module. With reference to FIG. 7, first, insulating substrate 10, heat dissipation member 20, the semiconductor elements, that is, IGBT 41, diode 42, and the like, first solder 51, and conductive member 59 are prepared.

Insulating substrate 10 includes base member 11. At least one conductor layer 12 is bonded onto one surface 11A of base member 11, and at least one conductor layer 13 is bonded onto other surface 11B on a side opposite from one surface 11A. The first region on one surface 11A where conductor layer 12 is not bonded and the second region on other surface 11 B where conductor layer 13 is not bonded are considered. A difference in area between the first region and the second region is adjusted. This causes the direction and degree of the curvature of the convex shape of insulating substrate 10 after each member is bonded by solder to be adjusted. Therefore, although insulating substrate 10 illustrated in FIG. 7 looks like insulating substrate 10 is not curved, insulating substrate 10 is actually slightly curved at this point of time.

Each of the above-described members is positioned to constitute power module 100 illustrated in FIGS. 1 and 2. That is, plate-shaped first solder 51 is disposed between heat dissipation member 20 and conductor layer 13 of insulating substrate 10. Plate-shaped conductive member 59 is disposed between conductor layer 12 of insulating substrate 10, and IGBT 41 and diode 42. Such members are each positioned ready to be bonded.

FIG. 8 is a schematic cross-sectional view of the power module according to the first embodiment illustrated in FIG. 2, illustrating a second process of the manufacturing method for the power module. With reference to FIG. 8, in the state illustrated in FIG.

7, the above-described members are bonded by first solder 51 and conductive member 59 using a reflow device. This causes all the above-described members to simultaneously bonded. That is, heat dissipation member 20 and insulating substrate 10 are bonded by first solder 51. IGBT 41 and diode 42 are bonded to insulating substrate 10. As described above, the direction and degree of the curvature of the convex shape of insulating substrate 10 after bonding are determined by conductor layers 12, 13 of insulating substrate 10. Therefore, insulating substrate 10 is bonded to heat dissipation member 20 to cause the main surface of insulating substrate 10 to curve so as to have a shape convex toward heat dissipation member 20. In order for insulating substrate 10 to have the convex shape, first solder 51 is formed thicker at the edges than at the center in the plan view.

As described above, the bonding between heat dissipation member 20 and insulating substrate 10 by first solder 51 and the bonding between insulating substrate 10, and IGBT 41 and the like by conductive member 59 may be performed at the same time. The bonding, however, may be performed at different timings rather than at the same time. Note that, in this case, it is preferable that heat dissipation member 20 and insulating substrate 10 be first bonded together by first solder 51, and then insulating substrate 10, and IGBT 41 and the like be bonded together by conductive member 59. If insulating substrate 10, and IGBT 41 and the like are first bonded together by conductive member 59, and then insulating substrate 10 and heat dissipation member 20 are bonded together, conductive member 59 under IGBT 41 may be melted again by heat generated when insulating substrate 10 and heat dissipation member 20 are bonded together. When conductive member 59 is melted again, IGBT 41 and the like may be displaced relative to insulating substrate 10 due to residual stress applied to a bonding wire (not illustrated) used for forming a circuit in IGBT 41. From the viewpoint of preventing such a problem, the bonding is preferably performed in the above-described order.

As described above, the following processes are performed after the process of bonding, with first solder 51, heat dissipation member 20 and insulating substrate 10 together and the process of bonding IGBT 41 and diode 42 to insulating substrate 10 with conductive member 59. Second solder 52 and frame member 60 are prepared.

Signal electrode 71 and electrode plate 30 are partially embedded in frame member 60. On the left side of frame member 60 in FIG. 8, signal electrode 71 is insert-molded into frame member 60 so as to be partially exposed from frame member 60. The second portion of main terminal-side edge 33 that is a part of main body 30A of electrode plate 30, the bent portion, and the rightmost region in FIG. 8 of the portion of main body 30A along the XY plane are embedded in the right side of frame member 60 in FIG. 8. Electrode plate 30 is insert-molded so that such regions are embedded. This causes first portion 31 of main terminal-side edge 33 as main terminal 72 to be exposed upward from frame member 60, and causes the portion of electrode plate 30 along the XY plane and semiconductor element-side edge 34 to be exposed in the region surrounded by frame member 60.

Plate-shaped second solder 52 is disposed on IGBT 41 and diode 42. The portion of electrode plate 30 along the XY plane is disposed on second solder 52. Note that, when the main surface of electrode plate 30 is curved along the convex shape of insulating substrate 10 as illustrated in FIG. 2, it is preferable that electrode plate 30 be curved in advance by a publicly-known method. Alternatively, a pre-curved electrode plate 30 may be purchased. This causes second solder 52, electrode plate 30, and frame member 60 to be positioned ready to be bonded.

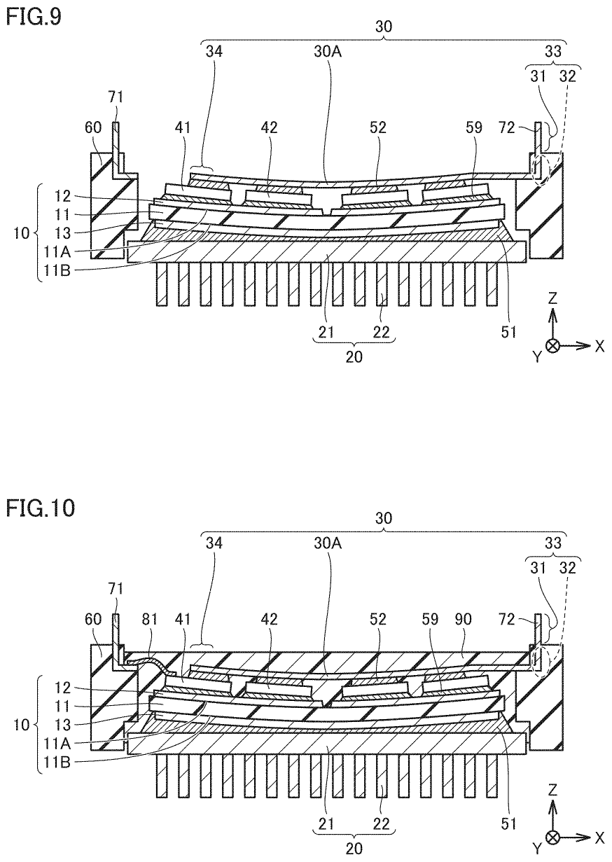

FIG. 9 is a schematic cross-sectional view of the power module according to the first embodiment illustrated in FIG. 2, illustrating a third process of the manufacturing method for the power module. With reference to FIG. 9, frame member 60 in which second portion 32 of main terminal-side edge 33 is embedded is disposed so as to surround insulating substrate 10 at a distance from insulating substrate 10. Heating using a reflow furnace causes second solder 52 to bond electrode plate 30 to IGBT 41 and diode 42. That is, electrode plate 30 is bonded to IGBT 41 and diode 42 by second solder 52 so as to overlap at least a part of IGBT 41 and diode 42. More specifically, in this process, the main electrodes (not illustrated) of IGBT 41 and diode 42 are bonded, by second solder 52, to the portion of electrode plate 30 extending along the XY plane.

Further, base plate 21 of heat dissipation member 20 and frame member 60 are bonded together by an adhesive (not illustrated).

FIG. 10 is a schematic cross-sectional view of the power module according to the first embodiment, illustrating a fourth process of the manufacturing method for the power module. With reference to FIG. 10, the portion of signal electrode 71 exposed to the inside of frame member 60 is electrically connected to the main electrode (not illustrated) or the like of IGBT 21 by bonding wire 81. Subsequently, liquid encapsulant 90 is injected into the region surrounded by frame member 60 and heat dissipation member 20. It is heated, for example, at 150° C. for 1.5 hours. This cures encapsulant 90. As a result, the members surrounded by frame member 60 are electrically insulated from each other.

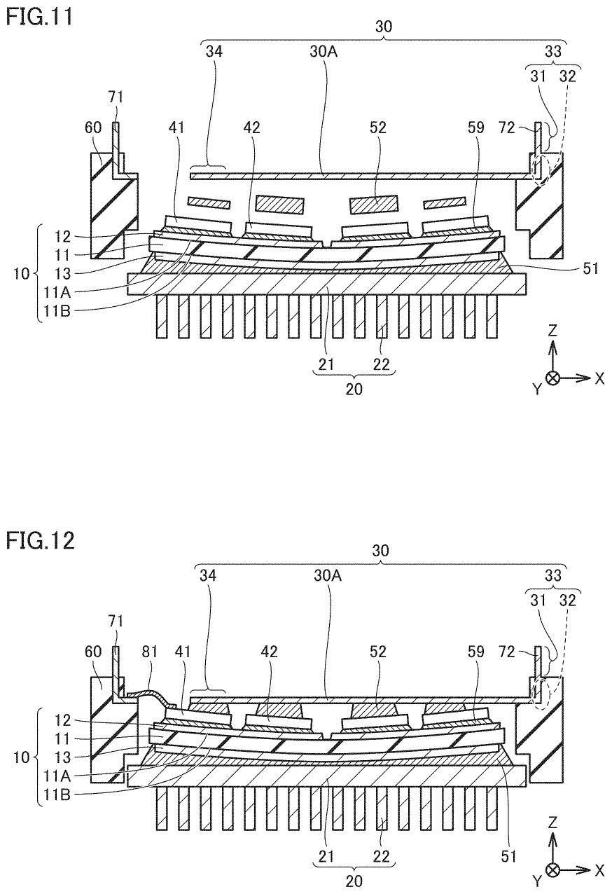

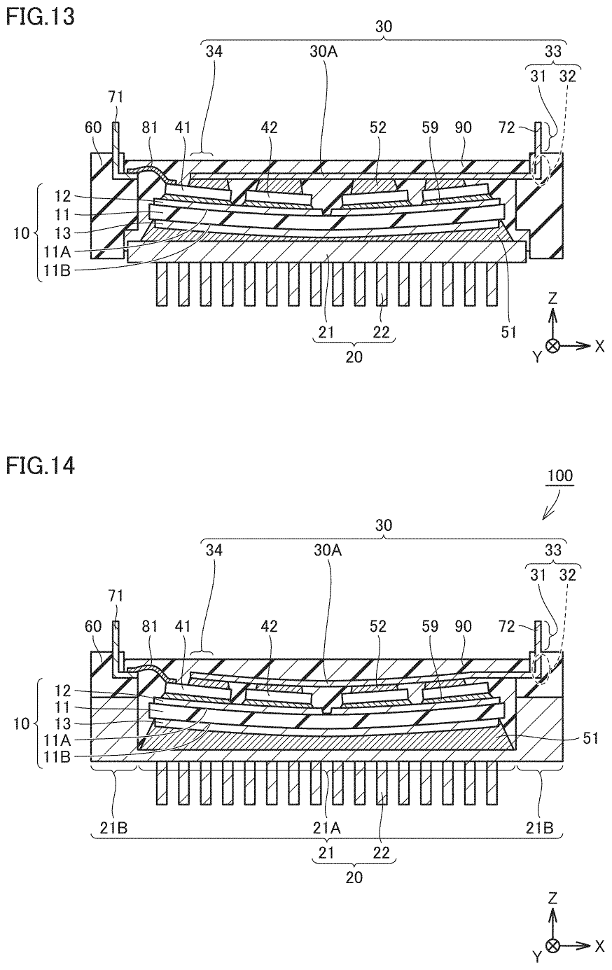

Next, the manufacturing method for power module 100 illustrated in FIG. 1 will be described with reference to FIGS. 11 to 13. FIG. 11 is a schematic cross-sectional view of the power module according to the first embodiment illustrated in FIG. 1, illustrating a first process of the manufacturing method for the power module. FIG. 12 is a schematic cross-sectional view of the power module according to the first embodiment illustrated in FIG. 1, illustrating a second process of the manufacturing method for the power module. FIG. 13 is a schematic cross-sectional view of the power module according to the first embodiment illustrated in FIG. 1, illustrating a third process of the manufacturing method for the power module. With reference to FIGS. 11 to 13, even for the example where main body 30A of electrode plate 30 has almost no curved portion as illustrated in FIG. 1, the manufacturing method is basically the same as for the example where main body 30A of electrode plate 30 has a shape along the convex shape as illustrated in FIGS. 7 to 10. First, as in FIG. 7, each member is prepared and positioned. Next, as illustrated in FIG. 11, processing basically the same as illustrated in FIG. 8 is performed. Note that, as illustrated in FIG. 11, main body 30A of electrode plate 30 has almost no curved portion. Further, as illustrated in FIG. 11, from the viewpoint of bonding plate-shaped electrode plate 30 and the semiconductor element together, second solder 52 adjacent to the center is made larger in thickness than second solder 52 adjacent to the edges. Next, as illustrated in FIG. 12, processing basically the same as illustrated in FIG. 9 is performed. Next, as in FIG. 13, processing basically the same as illustrated in FIG. 10 is performed.

Note that, under the manufacturing method illustrated in FIGS. 7 to 10 and FIGS. 11 to 13, as illustrated in FIGS. 3 and 4, conductor layer 12 on one surface 11A may be formed thicker than conductor layer 13 on other surface 11B. Alternatively, under the manufacturing method illustrated in FIGS. 7 to 10 and FIGS. 11 to 13, as illustrated in FIGS. 5 and 6, other conductor layer 12a may be bonded to between conductor layer 12 on one surface 11A, and IGBT 41 and diode 42 so as to overlap conductor layer 12. Accordingly, the curvature of the convex shape is adjusted such that insulating substrate 10 is curved so as to have a shape convex toward heat dissipation member 20.

Next, a description will be given of the actions and effects of the present embodiment together with the background and problem of the present embodiment.

There is a strong demand for making power modules for automobile use compact and lightweight. For this reason, in such a power module for automobile use, it is necessary to arrange semiconductor elements to which a high voltage and a large current can be applied at high density. As a result, thermal interference between the plurality of semiconductor elements thus arranged may become a problem, and thus efficient heat dissipation to a heat dissipation member is an important design requirement. Further, the power module is mounted on transportation equipment, so that high reliability is required from the viewpoint of stably transporting passengers and the like.

A base plate and fins constituting the heat dissipation member are often made of copper or aluminum having high thermal conductivity. Copper and aluminum, however, are largely different in thermal expansion coefficient from aluminum nitride of which a base member of an insulating substrate is made and silicon of which a semiconductor element is made. Power modules for automobile use and electric-train use generate a large amount of heat, so that it is necessary to bond the heat dissipation member and the insulating substrate together with solder that is higher in thermal conductivity than heat dissipation grease. For this reason, large thermal stress is applied to a joint between the heat dissipation member and the insulating substrate and may cause a crack in the joint in evaluation of long-term reliability such as temperature cycle resistance.

Further, bonding the insulating substrate to the heat dissipation member with solder may unintentionally cause the insulating substrate to curve or incline relative to the horizontal direction. In a case where wire bonding is performed for forming a circuit on the insulating substrate, the IGBT, or the like having such an inclination or the like, contact of a wire tool varies for each place where the wire bonding is to be performed. For this reason, it is necessary to adjust the contact of the wire tool for each of the plurality of semiconductor elements, that is, each time the wire bonding is performed at different positions having different inclinations. When this adjustment is insufficient, the wire tool may damage the semiconductor element to make it difficult to wire-bond wiring with high reliability.

Therefore, power module 100 as the semiconductor device according to the present embodiment includes insulating substrate 10, heat dissipation member 20, and electrode plate 30. IGBT 41 and diode 42 as semiconductor elements are mounted on insulating substrate 10. Heat dissipation member 20 is bonded to insulating substrate 10 by first solder 51. Electrode plate 30 is disposed so as to overlap at least a part of the semiconductor elements. The main surface of insulating substrate 10 is curved so as to have a shape convex toward heat dissipation member 20 and extending over the plurality of semiconductor elements. First solder 51 is thicker at the edges than at the center in the plan view. Each semiconductor element is bonded to electrode plate 30 by second solder 52.

Heat dissipation member 20 is bonded to insulating substrate 10 by, for example, first solder 51 high in thermal conductivity than heat dissipation grease. Therefore, a large amount of heat generated by the semiconductor elements is dissipated from first solder 51 to heat dissipation member 20 with high efficiency.

The main surface of insulating substrate 10 is curved so as to have a shape convex toward heat dissipation member 20, and first solder 51 is thicker at the edges than at the center. This makes it possible to first reduce concentration of thermal stress generated in the joint between insulating substrate 10 and heat dissipation member 20 by first solder 51 on the edges in the plan view. Although thermal strain on the edges of first solder 51 in the plan view increases, first solder 51 increases in thickness toward the edges due to the convex shape, so that the thermal strain on the edges can be reduced. This can make long-term reliability such as temperature cycle resistance higher, and specifically can curb the generation of cracks in first solder 51. Second, first solder 51 is made thinner at the center where the temperature becomes highest due to thermal interference, so that the thermal resistance is reduced. This allows heat to be dissipated from first solder 51 to heat dissipation member 20 with high efficiency.

The semiconductor element is bonded to electrode plate 30 by second solder 52. This eliminates the need of adjustment of the contact of the wire tool based on the inclination angle of insulating substrate 10 and the semiconductor element from the horizontal direction, which may occur when power module 100 is electrically connected to the outside by, for example, direct wire bonding to the semiconductor element. It is therefore possible to prevent the wire tool from damaging the semiconductor element due to the adjustment of the contact of the wire tool. This makes the reliability of electrical connection between the semiconductor element inclined from the horizontal direction due to the curvature of insulating substrate 10 and the outside of power module 100 high as compared with a case where the electrical connection is made by a bonding wire.

In power module 100, insulating substrate 10 includes base member 11. At least one conductor layer 12 is bonded onto one surface 11A of base member 11, and at least one conductor layer 13 is bonded onto other surface 11B on a side opposite from one surface 11A. First solder 51 bonds with the whole surface of conductor layer 13 on other surface 11B. First solder 51 gradually increases in thickness from the center toward the edges in the plan view. Such a configuration may be employed and can produce the same actions and effects as described above.

It is preferable that power module 100 further include frame member 60 disposed so as to surround insulating substrate 10 at a distance from insulating substrate 10.

In the present embodiment, the semiconductor element and electrode plate 30 are bonded together by second solder 52. Therefore, for example, unlike bonding at room temperature by wire bonding, second solder 52 is heated and melted at the time of bonding. This heating may unintentionally cause insulating substrate 10 to curve. This makes insulating substrate 10 deformed more than expected to interfere with frame member 60 to generate stress in insulating substrate 10, which may cause a corner of insulating substrate 10 to chip or crack.

Therefore, as described above, frame member 60 is disposed at a distance from insulating substrate 10 and the semiconductor element. This causes the space around insulating substrate 10 and first solder 51 in the plan view to be covered with encapsulant 90 made of a silica filler-containing epoxy resin or the like. Base member 11 of insulating substrate 10 and heat dissipation member 20 are largely different in thermal expansion coefficient from each other, and there is a possibility that first solder 51 will crack during the evaluation of the temperature cycle resistance of first solder 51. Interposing encapsulant 90 between base member 11 and heat dissipation member 20, however, can make differences in thermal expansion coefficient between base member 11 and encapsulant 90 and between heat dissipation member 20 and encapsulant 90 smaller than the above. This makes the possibility that first solder 51 will crack during the evaluation of long-term reliability such as temperature cycle resistance lower and makes the reliability of power module 100 higher.

In power module 100 described above, electrode plate 30 is disposed so as to face insulating substrate 10 in frame member 60. The main surface of electrode plate 30 may be curved along the convex shape of insulating substrate 10. This makes the thickness of second solder 52 bonding electrode plate 30 and the semiconductor element together uniform among the plurality of semiconductor elements. This allows electrode plate 30 and the semiconductor element to be reliably and stably bonded together by second solder 52.

In power module 100, the semiconductor element includes diode 42 as the first semiconductor element, and IGBT 41 as the second semiconductor element disposed adjacent to the frame member in the plan view relative to the first semiconductor element. The maximum thickness of second solder 52 between electrode plate 30 and the first semiconductor element may be larger than the maximum thickness of second solder 52 between electrode plate 30 and the second semiconductor element. For example, when electrode plate 30 has a planar main surface that is not curved along the convex shape of insulating substrate 10 and is not curved along the XY plane or the like, such a configuration is employed.

That is, for example, when the second semiconductor element becomes higher in temperature than the first semiconductor element, second solder 52 in contact with the second semiconductor element is thinner than second solder 52 in contact with the first semiconductor element. This can make the total thermal resistance from the semiconductor element to heat dissipation member 20 lower.

In power module 100 described above, electrode plate 30 includes main terminal-side edge 33 as main terminal 72 and semiconductor element-side edge 34 that is an edge on a side opposite from the main terminal-side edge. Main terminal-side edge 33 has first portion 31 exposed outside frame member 60 and second portion 32 embedded in the frame member. Such a configuration is preferable. As described above, in the present embodiment, electrode plate 30 is integrally and electrically connected with main terminal 72. This can make the electrical connection structure between the semiconductor element and the outside of power module 100 simpler.

Power module 100 described above further includes encapsulant 90 as an encapsulant resin for encapsulating the semiconductor element. First solder 51 is in contact with encapsulant 90. This causes the space around insulating substrate 10 and first solder 51 in the plan view to be covered with encapsulant 90 made of a silica filler-containing epoxy resin or the like. Base member 11 of insulating substrate 10 and heat dissipation member 20 are largely different in thermal expansion coefficient from each other, and there is a possibility that first solder 51 will crack during the evaluation of the temperature cycle resistance of first solder 51. Interposing encapsulant 90 between base member 11 and heat dissipation member 20, however, can make differences in thermal expansion coefficient between base member 11 and encapsulant 90 and between heat dissipation member 20 and encapsulant 90 smaller than the above. This makes the possibility that first solder 51 will crack during the evaluation of long-term reliability such as temperature cycle resistance lower and makes the reliability of power module 100 higher.

Under the manufacturing method for the semiconductor device, that is, power module 100, according to the present embodiment, heat dissipation member 20 and insulating substrate 10 are bonded together by first solder 51. IGBT 41 and diode 42 as semiconductor elements are bonded to insulating substrate 10. After the process of bonding with first solder 51 and the process of bonding the semiconductor element, electrode plate 30 overlapping at least a part of the semiconductor element is bonded to the semiconductor element by second solder 52. Insulating substrate 10 is bonded to heat dissipation member 20 to cause the main surface of insulating substrate 10 to curve so as to have a shape convex toward heat dissipation member 20. First solder 51 is formed thicker at the edges than at the center in the plan view. The actions and effects produced by the above-described configuration are the same as the actions and effects produced by the basic configuration of power module 100, and thus no description will be given below of the actions and effects.

Under the manufacturing method for power module 100, insulating substrate 10 includes base member 11. At least one conductor layer 12 is bonded onto one surface 11A of base member 11, and at least one conductor layer 13 is bonded onto other surface 11B on a side opposite from one surface 11A. The curvature of the convex shape is adjusted by adjusting a difference in area between the first region on one surface 11A where conductor layer 12 is not bonded and the second region on other surface 11B where conductor layer 13 is not bonded. This makes it possible to control the direction and degree of the curvature of the main surface of insulating substrate 10.

Under the manufacturing method for power module 100, conductor layer 12 on one surface 11A may be formed thicker than conductor layer 13 on other surface 11B so as to adjust the curvature of the convex shape. Accordingly, the curvature of the convex shape is adjusted such that insulating substrate 10 is curved so as to have a shape convex toward heat dissipation member 20.

Under the manufacturing method for power module 100, the curvature of the convex shape may be adjusted by further including the process of bonding other conductor layer 12a to between conductor layer 12 on one surface 11A, and IGBT 41 and diode 42 so as to overlap conductor layer 12. Accordingly, the curvature of the convex shape is adjusted such that insulating substrate 10 is curved so as to have a shape convex toward heat dissipation member 20.

### Second Embodiment

FIG. 14 is a schematic cross-sectional view of a configuration of a power module according to a second embodiment. With reference to FIG. 14, in a power module 100 according to the present embodiment, base plate 21 of heat dissipation member 20 includes a first heat dissipation member portion 21A and a second heat dissipation member portion 21B. As with base plate 21 according to the first embodiment, first heat dissipation member portion 21A is a plate-shaped portion having a surface extending along the XY plane. An uppermost surface, in the Z direction, of first heat dissipation member portion 21A is bonded to the lower main surface of insulating substrate 10 by first solder 51. Second heat dissipation member portion 21B is disposed outside first heat dissipation member portion 21A in the plan view so as to be integrated with first heat dissipation member portion 21A. Second heat dissipation member portion 21B is disposed so as to surround first heat dissipation member portion 21A and first solder 51 on first heat dissipation member portion 21A in the plan view. Second heat dissipation member portion 21B is disposed at a position that is identical in coordinate in the Z direction to first heat dissipation member portion 21A and in a region extending upward in the Z direction from the position. Therefore, second heat dissipation member portion 21B is formed thicker than first heat dissipation member portion 21A so as to extend upward in the Z direction (toward insulating substrate 10). Frame member 60 is mounted on second heat dissipation member portion 21B formed thicker than first heat dissipation member portion 21A.

Therefore, first heat dissipation member portion 21A and second heat dissipation member portion 21B integrated with and disposed outside first heat dissipation member portion 21A form a depression. This depression houses first solder 51 and insulating substrate 10. In this respect, base plate 21 illustrated in FIG. 14 is different from base plate 21 illustrated in FIG. 1 that has only the flat plate member and does not form such a depression as illustrated in FIG. 1.

Next, a description will be given of actions and effects of the present embodiment. The present embodiment produces the following actions and effects in addition to the actions and effects produced by the basic configuration according to the first embodiment. The same applies to the following embodiments unless otherwise specified.

Power module 100 according to the present embodiment includes first heat dissipation member portion 21A and second heat dissipation member portion 21B. First heat dissipation member portion 21A is bonded to insulating substrate 10 by first solder 51. Second heat dissipation member portion 21B surrounds first heat dissipation member portion 21A and first solder 51 outside first heat dissipation member portion 21A in the plan view, and frame member 60 is mounted on second heat dissipation member portion 21B. In heat dissipation member 20, the depression formed by first heat dissipation member portion 21A and second heat dissipation member portion 21B houses first solder 51 and insulating substrate 10.

This can make first solder 51 thinner to lower rigidity of first solder 51 without lowering the rigidity of entire base plate 21 as compared with the first embodiment. This therefore can prevent first solder 51 from cracking during the evaluation of the long-term reliability such as temperature cycle resistance. Further, the thickness of frame member 60 disposed on second heat dissipation member portion 21B is reduced by the thickness of second heat dissipation member portion 21B. The PPS resin of which frame member 60 is made is low in adhesion to encapsulant 90. Therefore, making the dimension of frame member 60 in the Z direction smaller allows a reduction in area of the adhesion interface between encapsulant 90 and frame member 60, thereby reducing the possibility of separation between encapsulant 90 and frame member 60.

### Third Embodiment

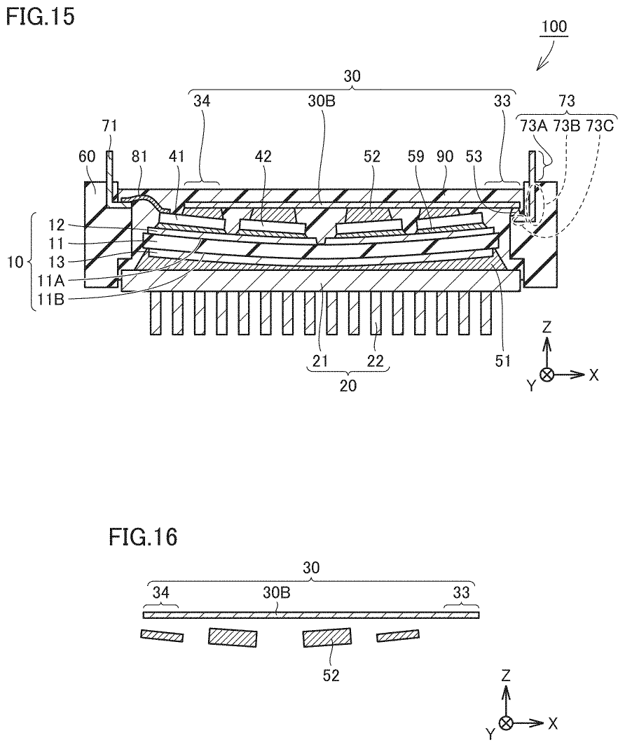

FIG. 15 is a schematic cross-sectional view of a configuration of a power module according to a third embodiment. With reference to FIG. 15, in power module 100 according to the present embodiment, electrode plate 30 has no region corresponding to main terminal 72, and further includes a main terminal 73 in frame member 60 on the right side of the drawing. Main terminal 73 corresponds to main terminal 72 according to the first embodiment. Main terminal 73, however, is not integrated with electrode plate 30, that is, not a part of main body 30A of electrode plate 30. Main terminal 73 is a member separate from electrode plate 30.

Main terminal 73 includes a first portion 73A, a second portion 73B, and a third portion 73C. First portion 73A corresponds first portion 31 of main terminal 72 illustrated in FIG. 1. First portion 73A is exposed outside frame member 60 so as to extend in the Z direction. Second portion 73B corresponds to second portion 32 of main terminal 72 illustrated in FIG. 1. Second portion 73B is embedded in frame member 60, and includes a portion where main terminal 73 is bent in FIG. 15. Third portion 73C serves as a connecting portion where main terminal 73 is connected to main terminal-side edge 33 of electrode plate 30 inside frame member 60. Note that third portion 73C serving as the connecting portion is exposed from inside frame member 60, but is embedded in encapsulant 90. Since third portion 73C is exposed from at least frame member 60 even when third portion 73C is embedded in encapsulant 90 in the form of a final product, third portion 73C may be expressed as “exposed from frame member 60”.

As described above, main terminal 73 is disposed as a member separate from electrode plate 30. Therefore, a main body 30B of electrode plate 30 has no main terminal, and has only a portion extending in the horizontal direction along the XY plane. Main body 30B of electrode plate 30 illustrated in FIG. 15, however, includes main terminal-side edge 33 and semiconductor element-side edge 34. Main terminal-side edge 33 is the rightmost region in the X direction of main body 30B illustrated in FIG. 15. Main terminal-side edge 33 is connected to main terminal 73. Semiconductor element-side edge 34 is a region on a side opposite from main terminal-side edge 33, that is, a region as the leftmost edge in the X direction of main body 30B illustrated in FIG. 15.

In FIG. 15, main terminal-side edge 33 of electrode plate 30 and third portion 73C serving as the connecting portion of main terminal 73 are bonded together by third solder 53. That is, a portion of main terminal-side edge 33 facing downward in the Z direction and a portion of third portion 73C facing upward in the Z direction are bonded together by third solder 53. Therefore, the rightmost region of main terminal-side edge 33 in the X direction in FIG. 15 preferably extends so as to overlap third portion 73C of main terminal 73 in the plan view. Main body 30B of electrode plate 30 and main terminal 73 according to the present embodiment are made of a metal material such as copper that is the same as the material of main body 30A of electrode plate 30 and signal electrode 71 according to the first embodiment.

Note that signal electrode 71, main terminal 73, and main body 30B of electrode plate 30 may be made of a single lead frame divided into three. Main body 30B is preferably made of a metal material such as copper.

In the present embodiment, electrode plate 30 and main terminal 73 are separate members, and are electrically connected to each other by third solder 53. In this respect, the present embodiment is different in configuration from the first and second embodiments in which electrode plate 30 is integrated with the main terminal to directly connect to the main terminal.

Next, a manufacturing method for power module 100 illustrated in FIG. 15 will be described with reference to FIGS. 16 to 19. Note that a description will be given below using an example where electrode plate 30 is not curved in advance and the main surface has a planar shape, but as illustrated in FIGS. 7 to 10, electrode plate 30 curved in advance may be used in the present embodiment. The same applies to the following embodiments.

FIG. 16 is a schematic cross-sectional view of the power module according to the third embodiment, illustrating a first process of the manufacturing method for the power module. With reference to FIG. 16, first, processing the same as illustrated in FIG. 7 is performed, and the members illustrated in FIG. 7 are bonded by first solder 51 and conductive member 59 using a reflow device. Second solder 52 and electrode plate 30 are prepared after the process of bonding the members using a reflow device. This corresponds to the process of preparing second solder 52 and frame member 60 after the bonding process illustrated in FIG. 8.

In FIG. 16, electrode plate 30 including plate-shaped main body 30B without the main terminal as illustrated in FIG. 15 and thus without the bent portion is prepared. Further, second solder 52 is thicker at the center than at the edges from the viewpoint of bonding plate-shaped electrode plate 30 and the semiconductor element together.

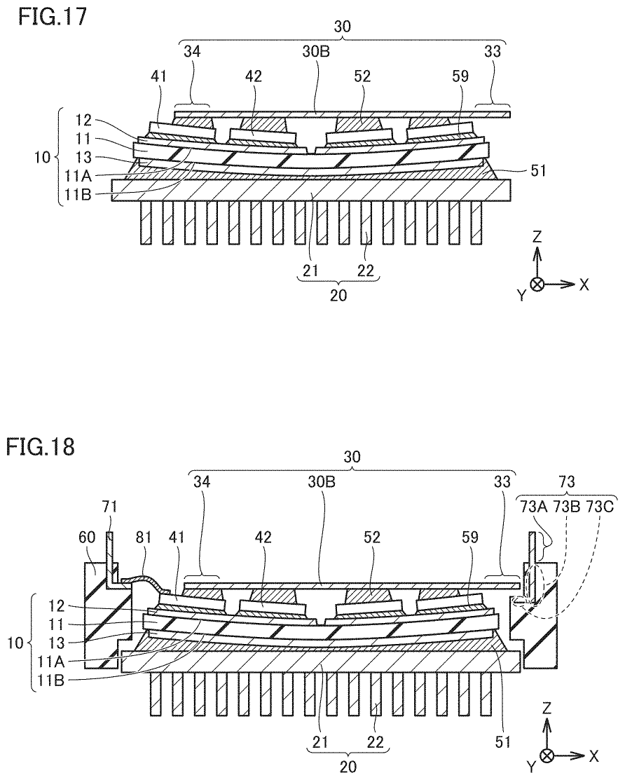

FIG. 17 is a schematic cross-sectional view of the power module according to the third embodiment, illustrating a second process of the manufacturing method for the power module. With reference to FIG. 17, as with the process illustrated in FIG. 9, electrode plate 30 is bonded to IGBT 41 and diode 42 by second solder 52 so as to overlap at least a part of IGBT 41 and diode 42.

FIG. 18 is a schematic cross-sectional view of the power module according to the third embodiment, illustrating a third process of the manufacturing method for the power module. With reference to FIG. 18, frame member 60 is prepared. On the left side of frame member 60 in FIG. 18, signal electrode 71 is insert-molded into frame member 60 so as to be partially exposed from frame member 60. On the right side of frame member 60 in FIG. 18, main terminal 73 is insert-molded into frame member 60 so as to be partially exposed from frame member 60.

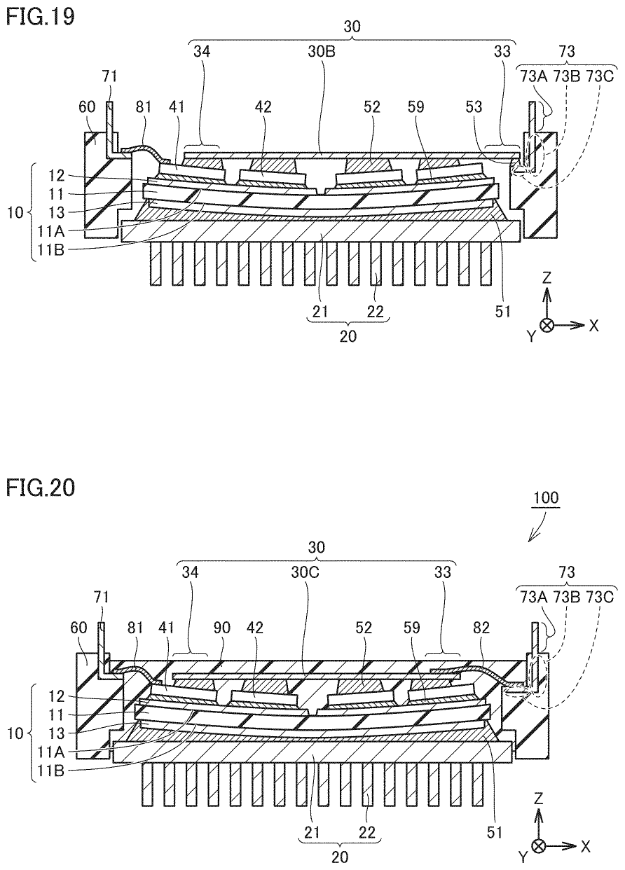

FIG. 19 is a schematic cross-sectional view of the power module according to the third embodiment, illustrating a fourth process of the manufacturing method for the power module. With reference to FIG. 19, in the state illustrated in FIG. 18, heating using a reflow furnace causes third solder 53 to bond electrode plate 30 and third portion 73C of main terminal 73 together. Subsequently, base plate 21 and frame member 60 are bonded together by the adhesive illustrated in FIG. 9, and the same processing as illustrated in FIG. 10 is performed to form power module 100 illustrated in FIG. 15.

Next, actions and effects of the present embodiment will be described. Power module 100 according to the present embodiment further includes main terminal 73. Main terminal 73 includes third portion 73C serving as the connecting portion exposed from inside frame member 60. Electrode plate 30 includes main terminal-side edge 33 connected to main terminal 73 and semiconductor element-side edge 34 that is an edge on a side opposite from main terminal-side edge 33. Main terminal-side edge 33 of electrode plate 30 and third portion 73C are bonded together by third solder 53.

Under the manufacturing method for power module 100 according to the present embodiment, frame member 60 disposed so as to surround insulating substrate 10 at a distance from insulating substrate 10 and in which main terminal 73 is embedded is prepared. After the process of bonding electrode plate 30 to the semiconductor element with second solder 52, electrode plate 30 and main terminal 73 are bonded together by third solder 53.

For example, as illustrated in FIGS. 15 to 19, a difference between the thickness of second solder 52 at the center in the plan view and the thickness of second solder 52 at the edges in the plan view may increase. In this case, even when insulating substrate 10 is unintentionally deformed, for example, curved greatly, it is possible to curb the generation of flaws such as a partial tearing of second solder 52. After electrode plate 30 and the semiconductor element are bonded together by second solder 52, main terminal 73 and electrode plate 30 are bonded together by third solder 53. Accordingly, adjusting the supply amount of third solder 53 and the like allows the joint made by third solder 53 to absorb stress applied to second solder 52 due to the deformation of electrode plate 30.

### Fourth Embodiment

FIG. 20 is a schematic cross-sectional view of a configuration of a power module according to a fourth embodiment. With reference to FIG. 20, a power module 100 according to the present embodiment is basically the same in configuration as power module 100 according to the third embodiment illustrated in FIG. 15. As with main body 30B, a main body 30C of electrode plate 30 has no main terminal and has only a portion extending in the horizontal direction along the XY plane. Therefore, in FIG. 20, the same components as the components illustrated in FIG. 15 are denoted by the same reference numerals, and no description will be given below of such components as long as their functions and the like are the same. Note that, in FIG. 20, main terminal-side edge 33 of electrode plate 30 and third portion 73C serving as the connecting portion of main terminal 73 are bonded together by a bonding wire 82. Bonding wire 82 extends in the X direction. Therefore, in main body 30C of electrode plate 30, the rightmost region of main terminal-side edge 33 in the X direction need not extend to a position where main terminal 73 is exposed from frame member 60, and main terminal-side edge 33 overlaps third portion 73C connected to electrode plate 30 in the plan view as illustrated in FIG. 15. In FIG. 20, main terminal-side edge 33 extends so as to overlap IGBT 41 on the right side in FIG. 20 in the plan view, and does not extend further rightward. Note that bonding wire 82 are preferably the same in material and dimensions as bonding wire 81. Main body 30C is preferably made of a metal material such as copper that is the same as the material of main bodies 30A, 30B.

In the present embodiment, electrode plate 30 and main terminal 73 are separate members, and are electrically connected to each other by bonding wire 82. In this respect, the present embodiment is different in configuration from the first and second embodiments in which electrode plate 30 is integrated with the main terminal to directly connect to the main terminal.

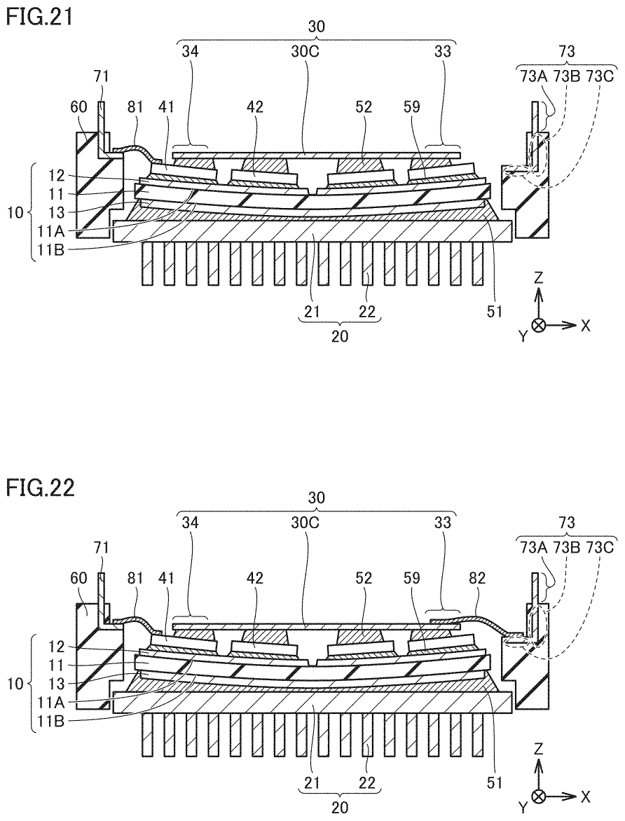

Next, a manufacturing method for power module 100 illustrated in FIG. 20 will be described with reference to FIGS. 21 and 22. FIG. 21 is a schematic cross-sectional view of the power module according to the fourth embodiment, illustrating a first process of the manufacturing method for the power module. With reference to FIG. 21, first, processing the same as illustrated in FIGS. 16 to 18 of the third embodiment is performed. The rightmost region of main terminal-side edge 33 of plate-shaped main body 30C located closest to main terminal 73 may be disposed on the left side as compared with the third embodiment.

FIG. 22 is a schematic cross-sectional view of the power module according to the fourth embodiment, illustrating a second process of the manufacturing method for the power module. With reference to FIG. 22, in the state illustrated in FIG. 21, electrode plate 30 and third portion 73C of main terminal 73 are bonded together by the wire bonding process, that is, by bonding wire 82. The subsequent processes are the same as the processes in the third embodiment. As a result, power module 100 illustrated in FIG. 20 is formed.

Next, a description will be given of actions and effects of the present embodiment. Power module 100 according to the present embodiment further includes main terminal 73. Main terminal 73 includes third portion 73C serving as the connecting portion exposed from inside frame member 60. Electrode plate 30 includes main terminal-side edge 33 connected to main terminal 73 and semiconductor element-side edge 34 that is an edge on a side opposite from main terminal-side edge 33. Main terminal-side edge 33 of electrode plate 30 and third portion 73C are bonded together by bonding wire 82.

Under the manufacturing method for power module 100 according to the present embodiment, frame member 60 disposed so as to surround insulating substrate 10 at a distance from insulating substrate 10 and in which main terminal 73 is embedded is prepared. After the process of bonding electrode plate 30 to the semiconductor element with second solder 52, electrode plate 30 and main terminal 73 are bonded together by the wire bonding process.

As described as the background and problem of the first embodiment, when wire bonding for forming a circuit is directly performed on the insulating substrate and the semiconductor element such as the IGBT having an inclination or the like, the wire tool may damage the semiconductor element. As in the present embodiment, however, electrode plate 30 is bonded to main terminal 73 by wire bonding via electrode plate 30 between the semiconductor element and main terminal 73. This allows a reduction in the number of bonding wires 81, 82 as compared with a case where wire bonding is directly performed on the semiconductor element. Further, the possibility that the wire tool will damage the semiconductor element due to the inclination of the surface of the semiconductor element caused by the curvature of insulating substrate 10 can be reduced, and the reliability of bonding wires 81, 82 can be improved.

### Fifth Embodiment

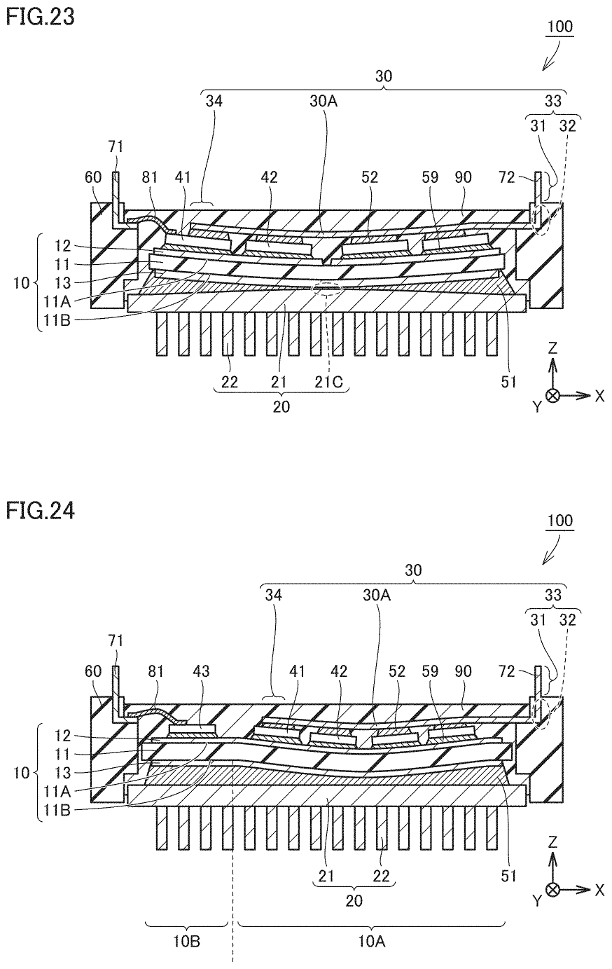

FIG. 23 is a schematic cross-sectional view of a configuration of a power module according to a fifth embodiment. With reference to FIG. 23, in power module 100 according to the present embodiment, a protrusion 21C is formed in heat dissipation member 20. Specifically, base plate 21 of heat dissipation member 20 has protrusion 21C whose tip is positioned to overlap, in the plan view, a region where the temperature becomes highest on other surface 11B, which is the back surface of insulating substrate 10, when the semiconductor element is in operation. As an example, FIG. 23 illustrates an example where the temperature becomes highest at the center of insulating substrate 10 in the plan view when the semiconductor element is in operation. That is, protrusion 21C having the tip at a position of base plate 21 overlapping the center of insulating substrate 10 in the plan view. Precisely speaking, the semiconductor element reaches the highest temperature when the semiconductor element is in operation, but when viewed on the back surface of insulating substrate 10, heat is diffused to make the peak of heat distribution unclear, so that the temperature is highest at the center.

Protrusion 21C is formed on the uppermost surface where base plate 21 is in contact with first solder 51. The uppermost surface of base plate 21 is curved upward in a convex shape so as to make the uppermost surface at the tip of protrusion 21C highest in position. Therefore, the thickness of base plate 21 is largest at protrusion 21C. It is preferable that the tip of protrusion 21C be larger in thickness by about 0.1 mm than the edges of base plate 21 that are smallest in thickness.

Accordingly, first solder 51 in the region where the temperature becomes high can be made thinner, and first solder 51 at the edges can be made thicker. This reduces the thermal resistance of first solder 51 in the center region where the temperature becomes high, so that heat dissipation is increased. It is further possible to reduce the thermal strain applied to first solder 51 at the edges and to curb the generation of cracks in first solder 51.

### Sixth Embodiment

FIG. 24 is a schematic cross-sectional view of a configuration of a power module according to a sixth embodiment. With reference to FIG. 24, in power module 100 according to the present embodiment, insulating substrate 10 includes a curved portion 10A and a non-curved portion 10B. Curved portion 10A is a portion where the main surface of insulating substrate 10 is curved so as to have a shape convex toward heat dissipation member 20 as in the other embodiments described above. Non-curved portion 10B is a region where insulating substrate 10 is not curved, unlike curved portion 10A, and the main surface extends roughly flat along the XY plane. Curved portion 10A and non-curved portion 10B are arranged side by side in the horizontal direction. Therefore, in the present embodiment, with attention paid to only curved portion 10A of insulating substrate 10 excluding non-curved portion 10B, the center portion having a convex shape is formed at the center of curved portion 10A in the plan view. It is preferable that first solder 51 be thinnest at a position where first solder 51 overlaps the center of curved portion 10A. Note that, in the present embodiment as well as in the other embodiments, first solder 51 may be thinnest at a position where first solder 51 overlaps the center, in the overall plan view, of insulating substrate 10 obtained by combining curved portion 10A and non-curved portion 10B, and first solder 51 may be thicker at the edges.

As in the other embodiments, IGBT 41 and diode 42 are mounted on conductor layer 12 in curved portion 10A. On the other hand, a control semiconductor element 43 is mounted on conductor layer 12 in non-curved portion 10B. Control semiconductor element 43 is typically an integrated circuit (IC) in which a program for driving IGBT 41, diode 42, and the like is written, that is, a so-called microcomputer.

FIG. 24 illustrates conductor layer 12 extending from curved portion 10A to non-curved portion 10B. Conductor layer 12, however, may be divided into separate members, each provided for a corresponding one of curved portion 10A and non-curved portion 10B.

Power module 100 may have such a configuration. Control semiconductor element 43 generates little heat. Therefore, first solder 51 at the position where first solder 51 overlaps control semiconductor element 43 may be entirely formed as thick as the edges of first solder 51. That is, the thickness of first solder 51 may be substantially uniform over non-curved portion 10B. Accordingly, the surface of control semiconductor element 43 in non-curved portion 10B is disposed along the horizontal direction, that is, so as to have almost no inclination. Therefore, control semiconductor element 43 can reduce the possibility of damaging the control semiconductor element due to the inclination when wire bonding is performed on control semiconductor element 43.

### Seventh Embodiment

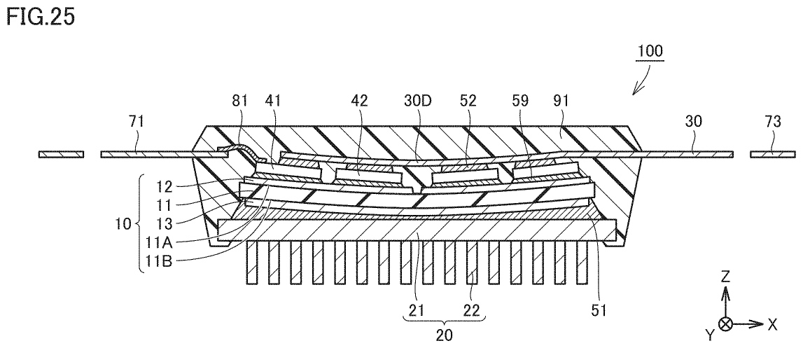

FIG. 25 is a schematic cross-sectional view of a configuration of a power module according to a seventh embodiment. With reference to FIG. 25, power module 100 need not include frame member 60. In the present embodiment, with at least a part of the lowermost surface of base plate 21 and all fins 22 exposed outside, encapsulant 91 of power module 100 encapsulates each of the other members. Since frame member 60 is not provided, encapsulant 91 forms the outermost surface of power module 100.

In FIG. 25, a main body 30D of electrode plate 30 is disposed as a member separate from main terminal 73 and signal electrode 71. Note that main body 30D has only a portion extending in the horizontal direction along the XY plane. As illustrated in FIG. 25, in the present embodiment, signal electrode 71 and main terminal 73 may be arranged side by side on the same plane so as to be along the same plane as the XY plane where main body 30D extends. Main body 30D and signal electrode 71 are connected by bonding wire 81 as in the other embodiments. Main body 30D and main terminal 73 may be connected by any means, specifically, by either third solder 53 or bonding wire 82.

Note that signal electrode 71, main terminal 73, and main body 30D of electrode plate 30 may be made of a single lead frame divided into three. Alternatively, as in the first embodiment, main body 30D and main terminal 73 may be integrated with each other. Therefore, main body 30D is preferably made of a metal material such as copper.

Encapsulant 91 is preferably a silica filler-containing epoxy resin formed by transfer molding. Specifically, during the transfer molding, for example, the following processing is performed. Members such as base plate 21, insulating substrate 10, and the semiconductor element illustrated in FIG. 25 are laminated in a mold so as to include at least a part of main body 30D and signal electrode 71 and fixed, that is, sandwiched. At this time, the mold is heated to 170° C. The mold is a machined stainless steel. Next, solid resin tablets for transfer molding are poured into the mold with the solid resin tablet heated and pressurized. The mold is heated in its entirety at 170° C. for 1 minute to cure the resin. Subsequently, all the components including encapsulant 91 as the cured resin are removed from the mold. All the components removed from the mold are heated in an oven at 170° C. for 2 hours. Accordingly, power module 100 including encapsulant 91 illustrated in FIG. 25 is formed. Since the actions and effects of the present embodiment are the same as the actions and effects of the first embodiment, no description will be given below of the actions and effects.

### FIRST EXAMPLE

The long-term reliability such as temperature cycle resistance, as described above, of first solder 51 by which insulating substrate 10 and heat dissipation member 20 are bonded together was evaluated. Specifically, a sample was prepared for each of the following three types of power modules.

A first sample has a configuration similar to the configuration of power module 100 illustrated in FIG. 1. That is, the first sample is curved to cause the main surface of insulating substrate 10 to curve so as to have a shape convex toward heat dissipation member 20. In the first sample, the thickness of first solder 51 illustrated in FIG. 1 is 0.2 mm at the center and 0.4 mm at the edges. That is, as in the first embodiment, first solder 51 is thicker at the edges than at the center. A second sample is basically the same in configuration as the first sample, but the thickness of first solder 51 is the same at the center and the edges. In the second sample, the thickness of first solder 51 is 0.3 mm at both the center and the edges. A third sample is basically the same in configuration as the first sample, but the thickness of first solder 51 is 0.3 mm at the center and 0.2 mm at the edges. That is, first solder 51 is thinner at the edges than at the center, contrary to the first embodiment.

The three samples were each placed in an atmosphere at 125° C. for 30 minutes and placed in an atmosphere at 40° C. below zero for 30 minutes. Temperature cycle testing was conducted in which the above-described processing regarded as one cycle was repeated a plurality of times. Subsequently, an ultrasonic testing image of first solder 51 was taken.

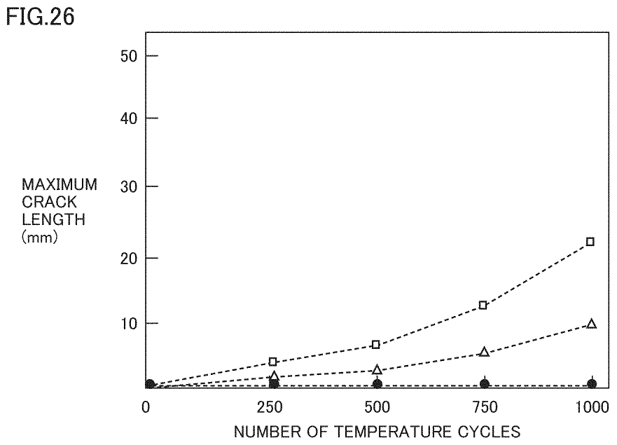

FIG. 26 is a graph showing a result of measuring a maximum length of cracks formed at an edge of the first solder. The horizontal axis of FIG. 26 indicates the number of times the above-described one cycle is repeated for each sample. The vertical axis of FIG. 26 indicates the maximum length of cracks at the edge of first solder 51 after the above-described one cycle is repeated a plurality of times. Note that black circles in FIG. 26 indicate the first sample. White triangles in FIG. 26 indicate the second sample. White squares in FIG. 26 indicate the third sample.

With reference to FIG. 26, for the first sample, cracks hardly developed even after the cycle was repeated 1000 times. On the other hand, for the second sample, after the cycle was repeated 1000 times, cracks developed from the edge of first solder 51 by about 10 mm. For the third sample, after the cycle was repeated 1000 times, cracks developed from the edge of first solder 51 by about 22 mm.

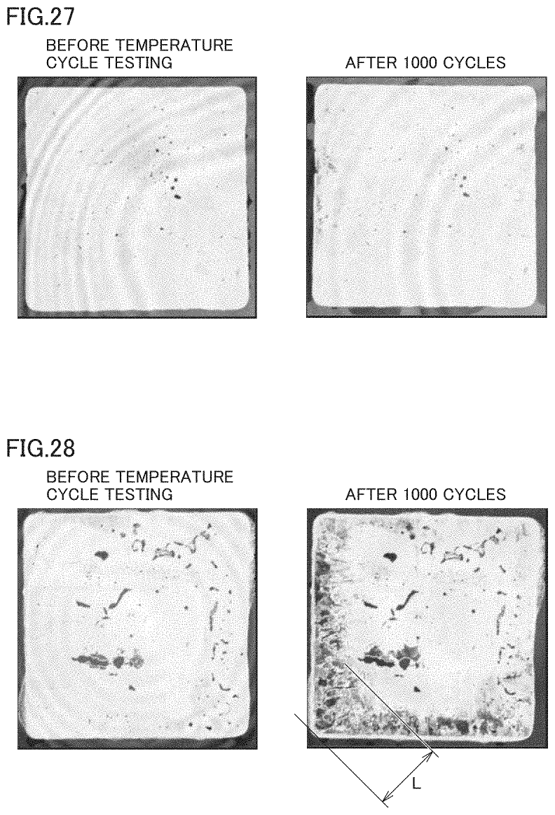

FIG. 27 is an ultrasonic testing image of the edge of the first solder after the temperature cycle testing conducted on the first sample. FIG. 28 is an ultrasonic testing image of the edge of the first solder after the temperature cycle testing conducted on the third sample. With reference to FIG. 27, for the first sample, cracks in first solder 51 hardly developed before the temperature cycle testing and after 1000 cycles. On the other hand, with reference to FIG. 28, for the third sample, cracks in first solder 51 hardly developed before the temperature cycle testing, whereas cracks having a length L in the drawing were formed after 1000 cycles. It was therefore confirmed that making the first solder thicker at the edges than at the center in the plan view can curb the generation of cracks.

The features described in (each example included in) each of the above-described embodiments may be appropriately combined and applied within a range where there is no technical contradiction. For example, as in the third and fourth embodiments, a configuration including main bodies 30B, 30C and main terminal 73 may be applied to the fifth and sixth embodiments.

It should be understood that the embodiments disclosed herein are illustrative in all respects and not restrictive. The scope of the present disclosure is defined by the claims rather than the above description, and the present disclosure is intended to include the claims, equivalents of the claims, and all modifications within the scope.

### REFERENCE SIGNS LIST

10: insulating substrate, 10A: curved portion, 10B: non-curved portion, 11: base member, 11A: one surface, 11B: other surface, 12, 13: conductor layer, 12a: other conductor layer, 20: heat dissipation member, 21: base plate, 21A: first heat dissipation member portion, 21B: second heat dissipation member portion, 21C: protrusion, 22: fin, 30: electrode plate, 30A, 30B, 30C, 30D: main body, 31, 73A: first portion, 32, 73B: second portion, 33: main terminal-side edge, 34: semiconductor element-side edge, 41: IGBT, 42: diode, 43: control semiconductor element, 51: first solder, 52: second solder, 53: third solder, 59: conductive member, 59a: fourth solder, 60: frame member, 71: signal electrode, 72, 73: main terminal, 73C: third portion, 81: bonding wire, 90, 91: encapsulant, 100: power module

1-17. (canceled)

18. A semiconductor device comprising:
an insulating substrate on which a semiconductor element is mounted;
a heat dissipation member bonded to the insulating substrate by first solder; and
an electrode plate disposed so as to overlap at least a part of the semiconductor element, wherein
the insulating substrate has a main surface curved so as to have a shape convex toward the heat dissipation member and extending over a plurality of the semiconductor elements,
the first solder is thicker at edges than at a center in a plan view, and
the semiconductor element is bonded to the electrode plate by second solder, the semiconductor device further comprising:
a frame member disposed so as to surround the insulating substrate at a distance from the insulating substrate, wherein
the semiconductor element includes a first semiconductor element and a second semiconductor element disposed near the frame member in the plan view as compared with the first semiconductor element, and
a maximum thickness of the second solder between the electrode plate and the first semiconductor element is larger than a maximum thickness of the second solder between the electrode plate and the second semiconductor element.

19. A semiconductor device comprising:
an insulating substrate on which a semiconductor element is mounted;
a heat dissipation member bonded to the insulating substrate by first solder; and
an electrode plate disposed so as to overlap at least a part of the semiconductor element, wherein
the insulating substrate has a main surface curved so as to have a shape convex toward the heat dissipation member and extending over a plurality of the semiconductor elements,
the first solder is thicker at edges than at a center in a plan view, and
the semiconductor element is bonded to the electrode plate by second solder, the semiconductor device further comprising:
a frame member disposed so as to surround the insulating substrate at a distance from the insulating substrate, wherein
the electrode plate is disposed so as to face the insulating substrate in the frame member, and
the electrode plate has a main surface curved along the convex shape of the insulating substrate.

20. The semiconductor device according to claim 18, wherein
the insulating substrate includes a base member,
at least one conductor layer is bonded onto one surface of the base member and another surface on a side opposite from the one surface,
the first solder bonds with a whole surface of the conductor layer on the other surface, and
the first solder gradually increases in thickness from the center toward the edges in the plan view.

21. The semiconductor device according to claim 19, wherein
the heat dissipation member includes a first heat dissipation member portion bonded to the insulating substrate by the first solder, and a second heat dissipation member portion disposed outside the first heat dissipation member portion to surround the first heat dissipation member portion and the first solder in the plan view, the frame member being mounted on the second heat dissipation member portion, and
in the heat dissipation member, a depression formed by the first heat dissipation member portion and the second heat dissipation member portion houses the first solder and the insulating substrate.

22. The semiconductor device according to claim 18, wherein
the electrode plate includes a main terminal-side edge as a main terminal and a semiconductor element-side edge as an edge on a side opposite from the main terminal-side edge, and
the main terminal-side edge includes a first portion exposed outside the frame member and a second portion embedded in the frame member.

23. The semiconductor device according to claim 18, further comprising a main terminal, wherein
the main terminal includes a connecting portion exposed from inside the frame member,
the electrode plate includes a main terminal-side edge connected to the main terminal and a semiconductor element-side edge that is an edge on a side opposite from the main terminal-side edge, and
the main terminal-side edge of the electrode plate and the connecting portion are bonded together by third solder.

24. The semiconductor device according to claim 18, further comprising a main terminal, wherein
the main terminal includes a connecting portion exposed from inside the frame member,
the electrode plate includes a main terminal-side edge connected to the main terminal and a semiconductor element-side edge that is an edge on a side opposite from the main terminal-side edge, and
the main terminal-side edge of the electrode plate and the connecting portion are bonded together by a bonding wire.

25. The semiconductor device according to claim 18, wherein
the heat dissipation member has a protrusion whose tip is positioned to overlap, in the plan view, a region of the insulating substrate where temperature becomes highest.

26. The semiconductor device according claim 18, further comprising an encapsulant resin to encapsulate the semiconductor element, wherein
the first solder is in contact with the encapsulant resin.

27. A manufacturing method for a semiconductor device, comprising:
bonding, with first solder, a heat dissipation member and an insulating substrate together;
bonding a semiconductor element to the insulating substrate; and
bonding, with second solder, an electrode plate overlapping at least a part of the semiconductor element and the semiconductor element together after the bonding with the first solder and the bonding the semiconductor element, wherein
the insulating substrate is bonded to the heat dissipation member to cause a main surface to curve so as to have a shape convex toward the heat dissipation member, and
the first solder is formed thicker at edges than at a center in a plan view, the manufacturing method further comprising:
preparing a frame member disposed so as to surround the insulating substrate at a distance from the insulating substrate and having a main terminal embedded in the frame member; and
bonding, with third solder, the electrode plate and the main terminal together after the bonding the semiconductor element with the second solder.

28. A manufacturing method for a semiconductor device, comprising:
bonding, with first solder, a heat dissipation member and an insulating substrate together;
bonding a semiconductor element to the insulating substrate; and
bonding, with second solder, an electrode plate overlapping at least a part of the semiconductor element and the semiconductor element together after the bonding with the first solder and the bonding the semiconductor element, wherein
the insulating substrate is bonded to the heat dissipation member to cause a main surface to curve so as to have a shape convex toward the heat dissipation member, and
the first solder is formed thicker at edges than at a center in a plan view, the manufacturing method further comprising:
preparing a frame member disposed so as to surround the insulating substrate at a distance from the insulating substrate and having a main terminal embedded in the frame member; and
wire-bonding the electrode plate and the main terminal together after the bonding the semiconductor element with the second solder.

29. The manufacturing method for a semiconductor device according to claim 27, wherein
the insulating substrate includes a base member,
at least one conductor layer is bonded onto one surface of the base member and another surface on a side opposite from the one surface, and
the curvature of the convex shape is adjusted by adjusting a difference in area between a first region on the one surface where the conductor layer is not bonded and a second region on the other surface where the conductor layer is not bonded.

30. The manufacturing method for a semiconductor device according to claim 29, wherein
the curvature of the convex shape is adjusted by making the conductor layer on the one surface thicker than the conductor layer on the other surface.

31. The manufacturing method for a semiconductor device according to claim 29, further comprising, to adjust the curvature of the convex shape, bonding another conductor layer to between the conductor layer on the one surface and the semiconductor element so as to overlap the conductor layer.
